(19) United States
(12) Patent Application Publication
(10) Pub. No.: US 2005/0285199 A1
(43) Pub. Date: Dec. 29, 2005

(54) Method for producing a semiconductor circuit, and corresponding semiconductor circuit

(76) Inventors: Wolfgang Stadler, Munchen (DE); Werner Ertle, Neubiberg (DE); Bernd Goller, Munchen (DE); Michael Horn, Munchen (DE); Manfred Hermann, Munchen (DE); Giuseppe Miccoli, Munchen (DE)

Correspondence Address: BRINKS HOFER GILSON & LIONE, P.O. BOX 10395, CHICAGO, IL, 60610, US

(21) Appl. No.: 11/137,691

(22) Filed: May 25, 2005

(30) Foreign Application Priority Data
May 26, 2004 (DE) DE 102004025658.6

(51) Int. Cl. H01L 23/62

(52) U.S. Cl. 257/360

(57) ABSTRACT

A semiconductor circuit containing a pad for electrical bonding of the semiconductor circuit and a metal arrangement disposed beneath the pad. The metal arrangement is in a metal layer of the semiconductor circuit located closest to the pad and is electrically insulated from the pad and from a strip conductor located beneath the metal arrangement. More than one metal layer can contain a metal arrangement. Each metal arrangement is a full-area plate that overlaps all edges of the pad or has a regular structure of small square plates. If adjacent metal arrangements are constructed from small plates, the plates in one metal arrangement overlap to cover gaps in the other metal arrangement.

### PRIORITY

This application claims the benefit of priority to German Patent Application DE 10 2004 025658.6, filed on May 26, 2004, incorporated herein by reference.

### TECHNICAL FIELD

The present invention relates to a semiconductor circuit and production method thereof. More specifically, the present invention relates both to a method for producing a semiconductor circuit which has one or more pads provided for electrical bonding of the semiconductor circuit, and to a corresponding semiconductor circuit in which a metal arrangement is disposed in an electrically insulated manner beneath each pad.

### BACKGROUND

The production costs of a semiconductor circuit are nowadays determined essentially by the area used for the semiconductor circuit. A not insignificant portion (5-20%) of this area is taken up by I/O (input/output) cells, which provide an external interface for the semiconductor circuit. Consequently, design of these I/O cells is optimized with respect to the area used.

Recently, a pad concept has been used which enables power-supply lines to be routed even directly in a first metal layer beneath a pad. In this case, a convenient arrangement and optimized design of the strip conductors provide for a significant reduction of a pressure on active structures that occurs during probing and bonding. Compared with competing pad concepts, this pad concept offers the greatest realizable gain in area.

Under unfavorable conditions, however, during both probing and bonding, cracks may occur between an aluminum pad and strip conductors routed in an uppermost metal layer. A probability of such a crack occurring during probing then depends, essentially, on parameters used during probing (e.g., number of touch-downs, overdrive of the needle and shape of a needle tip used during probing).

It cannot be precluded that these cracks may become electrically active, i.e., the cracks result in a short circuit between the pad and a strip conductor located beneath it, thereby impairing the functional capability of the corresponding semiconductor circuit.

Although cracks can be almost entirely prevented during probing through the use of certain, generally very expensive, needle cards (vertical or membrane needle cards), cracking cannot be precluded in the particular case of inexpensive cantilever needle cards, which are frequently used in probing. In this case, the cracks generally end at the strip conductor disposed beneath a pad, directly beneath a point of impingement of a needle used in probing, preferably at a transition location between the strip conductor and an oxide that is disposed between the pad and the strip conductor.

It has also been possible to detect cracks in the case of semiconductor circuits which are only bonded, but not probed. In contrast with the cracks produced during probing, hitherto all examined cracks produced by bonding have not been electrically active. However, it cannot be precluded that, under certain conditions, electrical failure may nevertheless occur during the service life of a semiconductor circuit.

### BRIEF SUMMARY

Both a method for producing a semiconductor circuit and a semiconductor circuit which has at least one pad provided for electrical bonding of the semiconductor circuit are described. In the method and semiconductor circuit, a crack produced during probing or bonding is prevented from impairing the functional capability of the semiconductor circuit.

By way of introduction only, a semiconductor circuit and method of producing the semiconductor circuit are provided in various embodiments. The semiconductor circuit contains a pad for electrical bonding of the semiconductor circuit and a metal arrangement disposed beneath the pad. The metal arrangement is in a metal layer of the semiconductor circuit located closest to the pad and is electrically insulated from the pad and/or from a strip conductor located beneath the metal arrangement and/or other metal arrangements.

Either a single metal layer can contain the metal arrangement or more than one metal layer can contain a metal arrangement. In either case, each metal arrangement can be a full-area plate that overlaps all edges of the pad or have a regular structure of small square plates. If adjacent metal arrangements are constructed from small plates, the plates in one metal arrangement overlap to cover gaps in the other metal arrangement.

The foregoing summary has been provided only by way of introduction. Nothing in this section should be taken as a limitation on the following claims, which define the scope of the invention.

### BRIEF DESCRIPTION OF THE DRAWINGS

The following text explains in more detail a number of embodiments of the invention, using schematic drawings, in which:

FIG. 1 shows an exemplary embodiment according to the invention in which a full-area metal plate is disposed beneath a pad.

FIG. 2 shows a further exemplary embodiment according to the invention in which a plurality of metal arrangements is disposed beneath two pads.

FIGS. 3A and 3B show a structure of two adjacent metal arrangements.

Identical or functionally identical elements are provided with the same reference symbols in the figures.

### DETAILED DESCRIPTION OF THE PREFERRED EMBODIMENTS

A semiconductor circuit which has a pad such as a metal plate provided for electrical bonding of the semiconductor circuit, and production method thereof, are described. At least one metal arrangement is disposed in an electrically insulated manner beneath the pad, in a metal layer of the semiconductor circuit located closest to the pad.

The metal arrangement protects a portion of the semiconductor circuit, located beneath the metal arrangement against a short circuit due to a crack emanating from the pad. The crack may be caused by probing or bonding of the pad. In this context, a pad is understood to be a location or position of the semiconductor circuit at which probing or bonding can be performed, i.e., a usually metal surface from which the passivation has been removed. The metal arrangement is also electrically insulated from strip conductors located beneath the metal arrangement. Even if a short circuit between the pad and the metal arrangement occurs due to a crack, no functional impairment occurs in the semiconductor circuit since there is no unwanted short circuit between the strip conductor and the pad. Since the metal arrangement is also disposed so as to be electrically insulated in relation to the corresponding pad, a probability of cracking causing a short circuit between the pad and the metal arrangement is reduced, since cracking frequently occurs at an oxide-copper transition which, due to the electrical insulation of the metal arrangement, is absent, at least with respect to the metal arrangement. The metal arrangement may be produced as a full-area plate or with a regular structure.

A full-area plate may be used when only one metal arrangement is provided since, in this case, the risk of a crack breaking through the metal arrangement is minimized in comparison with a metal arrangement which is structured or provided with holes. By contrast, a regular structure may be used when a plurality of metal layers each containing a metal arrangement is present. In this case, the structure of the metal arrangements is matched to one another so as to minimize a probability of a crack emanating from the pad breaking through the metal arrangements. In comparison with a full-area metal plate, a structured metal arrangement increases the capacitance associated with the pad to a lesser extent than would be the case with a full-area metal plate.

If the metal arrangement is a full-area metal plate, the metal arrangement fully overlaps all of the edges of the pad. If the metal arrangement consists of a plurality of metal arrangements, some of these metal arrangements can fully overlap the pad, while the other metal arrangements do not overlap the pad. The fact that the pad is fully overlapped at all of its edges by a metal arrangement prevents a crack that starts at the pad and runs obliquely outwards from running past the metal arrangement and thereby resulting in a function-impairing short circuit of the semiconductor circuit.

The metal arrangement may be constructed from small metal plates. If multiple metal layers containing a metal arrangement are present, several or all metal arrangements may be constructed from small metal plates. The construction from small metal plates which are not electrically connected to one another permits the capacitance of the pad to increase by only the capacitance of the corresponding small metal plate (due to the lesser distance from the semiconductor circuit). The small metal plates may have the same surface area, for example, a square surface area. The small metal plates may be disposed with a regular distribution such as a checkerboard. An edge length of each small metal plate may be greater than a distance between two adjacent small metal plates.

Due to the small metal plates being constructed in the same way and disposed with a regular distribution, a method for producing the semiconductor circuit is simplified. Due to the distance between two adjacent small metal plates being less than the edge length of each small metal plate, gaps between the small metal plates are smaller than the small metal plates. The probability of a crack breaking through the metal arrangement consisting of small metal plates is thereby reduced.

An insulating layer is disposed between the metal arrangement and the pad and/or between the metal arrangement and a strip conductor located beneath the metal arrangement. If multiple metal arrangements are present, one or more insulating layers may be disposed between the individual metal arrangements.

These insulating layers reduce a probability of a developing crack resulting in a short circuit between the pad and a metal arrangement, or between two metal arrangements, or between a metal arrangement and any strip conductor disposed beneath the metal arrangement.

If the metal arrangement is constructed from a plurality of metal arrangements, first and second metal arrangements that are adjacent to each other may each be constructed from small metal plates. The square plates may be disposed in a regular manner such as a checkerboard, and small metal plates of the second metal arrangement being disposed such that they cover gaps between the small metal plates of the first metal arrangement. Since the two adjacent metal arrangements are mutually complementary in their structure, a probability of a crack breaking through both metal arrangements is further reduced.

If multiple metal arrangements are present, a first metal arrangement may be constructed from a plurality of small metal plates and a second metal arrangement, which is adjacent to the first metal arrangement, may be constructed in a lattice. In this case, the small metal plates in the first metal arrangement may be disposed such that they each respectively cover a hole in the second metal arrangement. In this case, the small metal plates in the first metal arrangement may have the shape of that hole which they cover. This complementary structuring of two adjacent metal arrangements likewise reduces a probability of a crack breaking through both metal arrangements.

A method for producing a semiconductor circuit is also provided which has multiple pads provided for electrical bonding of the semiconductor circuit. In this case, a metal arrangement is disposed in an electrically insulated manner beneath each pad in a metal layer of the semiconductor circuit located closest to the pad. This means that one or more metal arrangements may be disposed beneath a pad, including the possibility of one of these metal arrangements being disposed beneath a plurality of pads. In particular, one or more metal arrangements may be disposed per pad of the semiconductor circuit.

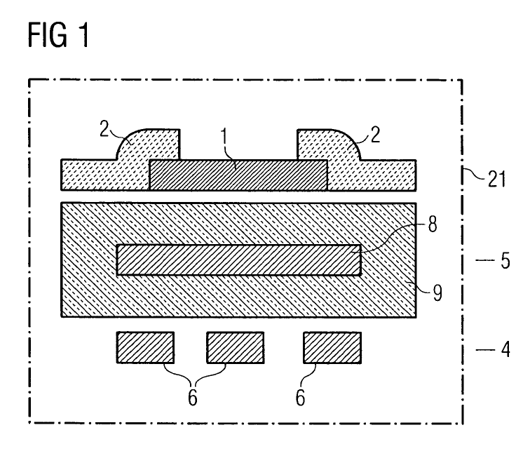

FIG. 1 shows a portion of a semiconductor circuit 21 in which a pad 1 is disposed in a passivation layer 2. In an uppermost metal layer 5 of the semiconductor circuit 21, a full-area metal plate 8 is disposed beneath the pad 1 such that it fully overlaps the pad, i.e., at all of its edges. In addition, strip conductors 6 are shown in a metal layer 4 beneath the metal plate 8. The metal plate 8 prevents a crack formed by the pad 1 due to a bonding or probing operation from resulting in a short circuit between the pad 1 and one of the strip conductors 6. This permits the metal plate 8 to be fully surrounded by an insulating layer 9, so that the metal plate 8 is electrically insulated from both the pad 1 and the strip conductors 6.

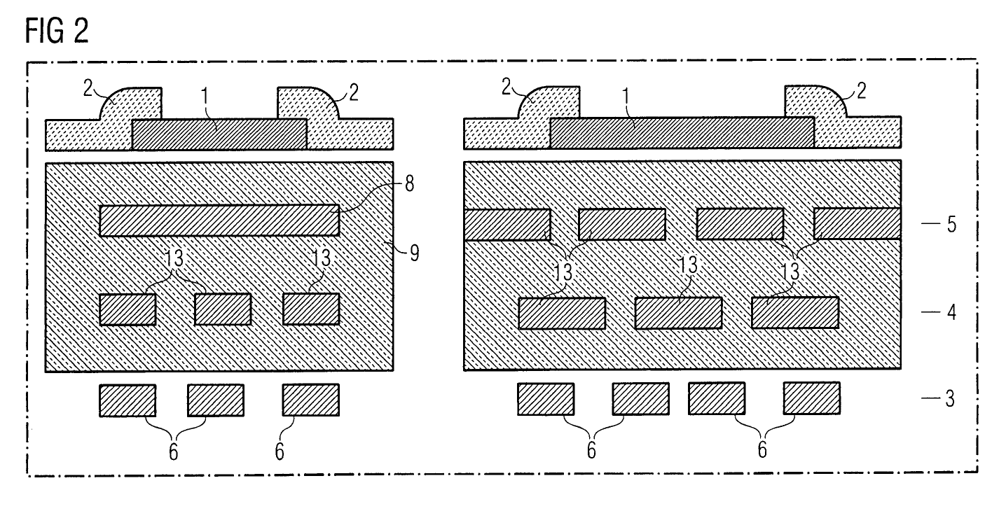

FIG. 2 shows another embodiment in which a portion of a semiconductor circuit 21 is shown with two pads 1 disposed in a passivation layer 2. Beneath each pad 1 there are respectively two metal arrangements. Beneath the left pad 1, there is a metal plate 8 in the uppermost metal layer 5. A metal arrangement 7 composed of small metal plates 13 is disposed in the metal layer 4 beneath the uppermost metal layer 5. Both metal arrangements fully overlap the pad 1. Strip conductors 6 are located only beneath the small metal plates 13 in a metal layer 3 further beneath the metal layer 4. As shown in FIG. 2, there is an insulting layer 9 between the metal plate 8 and the pad 1, between the small metal plates 13 and the strip conductors 6, and between the metal plate 8 and the small metal plates 13. Both the metal plate 8 and the small metal plates 13 are thus separately electrically insulated.

Beneath the right pad 1 there are two metal arrangements 7 disposed one beneath the other. Each of the metal arrangements 7 contains small metal plates 13. In this case, the small metal plates 13 are disposed such that the small metal plates 13 of one metal arrangement cover gaps between the small metal plates 13 of the other metal arrangement. Strip conductors 6 are located only beneath the lower metal arrangement.

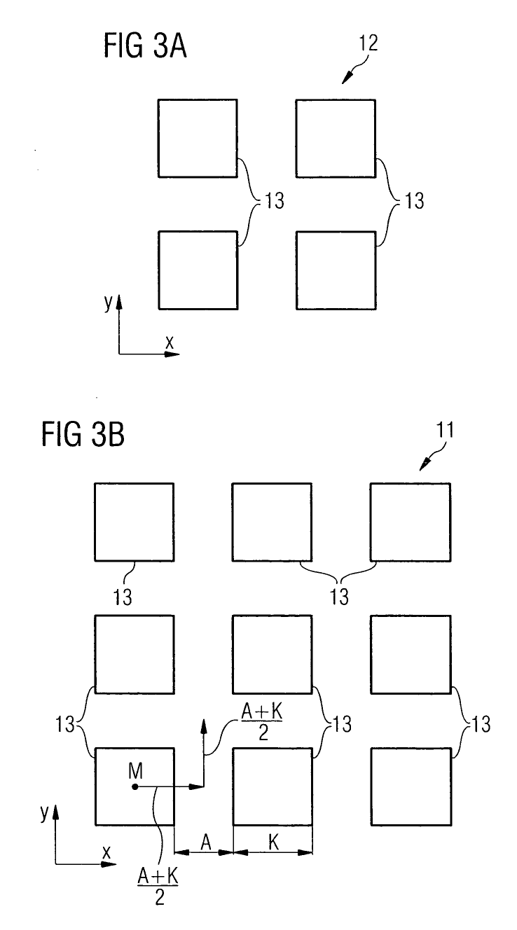

FIGS. 3A and 3B show two adjacent metal arrangements 11, 12, which each contain small square metal plates 13 arranged in a checkerboard manner and disposed beneath a pad (not shown). In this case, an edge length K of the small metal plates 13 and a distance A between two adjacent small metal plates 13 are equal in both metal arrangements. Furthermore, the distance A between the small metal plates 13 is less than the edge length K, and the small metal plates of both metal arrangements 11, 12 have the same orientation.

For example, the distance A between the small metal plates 13 may be half of the edge length K. In this case, proceeding from a middle starting point M of a small metal plate 13 in a metal arrangement 11, a middle point of an adjacently offset small metal plate 13 in the adjacent metal arrangement 12 can be calculated by respectively adding to the coordinates of the middle starting point M half of a sum of the edge length K and the distance A between the small metal plates 13.

Any of the above embodiments may be used for semiconductor circuits in which probing and/or bonding is performed with any devices provided for that purpose. However, the present invention is not limited to this application, but may also be used for semiconductor circuits in respect of which it is ensured that probing or bonding does not result in malfunctioning of the semiconductor circuit.

It is therefore intended that the foregoing detailed description be regarded as illustrative rather than limiting, and that it be understood that it is the following claims, including all equivalents, that are intended to define the spirit and scope of this invention. Nor is anything in the foregoing description intended to disavow scope of the invention as claimed or any equivalents thereof.

1. A semiconductor circuit, comprising:
a pad for electrical bonding of the semiconductor circuit; and
a metal arrangement disposed beneath the pad, in a metal layer of the semiconductor circuit located closest to the pad, the metal arrangement disposed in an electrically insulated manner.

2. The semiconductor circuit according to claim 1, wherein the metal arrangement is a full-area plate or comprises a regular structure.

3. The semiconductor circuit according to claim 1, wherein:
if only one metal layer containing a metal arrangement is disposed beneath the pad, the metal arrangement fully overlaps all edges of the pad; and
if a plurality of metal layers each containing a metal arrangement is disposed beneath the pad, at least one of the metal arrangements fully overlaps all edges of the pad.

4. The semiconductor circuit according to claim 1, wherein:
if only one metal layer containing a metal arrangement is disposed beneath the pad, the metal arrangement comprises small metal plates; and
if a plurality of metal layers each containing a metal arrangement is disposed beneath the pad, at least one of the metal arrangements comprises small metal plates.

5. The semiconductor circuit according to claim 4, wherein the small metal plates have at least one of the same surface area or are disposed with a regular distribution.

6. The semiconductor circuit according to claim 1, wherein the metal arrangement comprises small square metal plates which are disposed in a checkerboard manner, and a distance between adjacent small metal plates is equal in each case.

7. The semiconductor circuit according to claim 6, wherein an edge length of each small metal plate is greater than a distance between adjacent small metal plates.

8. The semiconductor circuit according to claim 1, wherein:
if only one metal layer containing a metal arrangement is disposed beneath the pad, an insulating layer is disposed at least one of between the metal arrangement and the pad or between the metal arrangement and a strip conductor located beneath the metal arrangement, and
if a plurality of metal layers each containing a metal arrangement is disposed beneath the pad, an insulating layer is disposed at least one of between an uppermost metal arrangement and the pad, between adjacent metal arrangements, or between a lowermost metal arrangement and a strip conductor located beneath the lowermost metal arrangement.

9. The semiconductor circuit according to claim 1, wherein the metal arrangement comprises first and second metal arrangements disposed adjacently, each of the first and second metal arrangements comprise small regular polygonal metal plates disposed in a regular manner, and the small metal plates of the second metal arrangement cover gaps between the small metal plates of the first metal arrangement.

10. The semiconductor circuit according to claim 1, wherein the metal arrangement comprises first and second metal arrangements disposed adjacently, each of the first and second metal arrangements comprise small square metal plates disposed in a checkerboard manner, a distance between two adjacent small metal plates in each of the first and second metal arrangements is equal, and the small metal plates of the second metal arrangement cover gaps between the small metal plates of the first metal arrangement.

11. The semiconductor circuit according to claim 10, wherein a middle point of each small metal plate in the second metal arrangement is offset from a middle point of a small metal plate disposed adjacently in the first metal arrangement by a distance which corresponds to half the distance between two small metal plates added to half an edge length of the small metal plates in the first metal arrangement, in orthogonal directions that are planar with the first and second metal arrangements.

12. The semiconductor circuit according to claim 1, wherein the metal arrangement comprises a first metal arrangement containing a plurality of small metal plates, and a second metal arrangement adjacent to the first metal arrangement, the second metal arrangement contains a lattice arranged such that, in each case, a hole in the second metal arrangement is disposed over one of the small metal plates in the first metal arrangement and has a shape which corresponds to a shape of the corresponding small metal plate.

13. A semiconductor circuit, comprising:
a plurality of pads for electrical bonding of the semiconductor circuit; and
a metal arrangement disposed beneath each pad, in a metal layer of the semiconductor circuit located closest to the pad, the metal arrangement disposed in an electrically insulated manner.

14. The semiconductor circuit according to claim 13, wherein a plurality of metal layers, each containing a metal arrangement, is disposed beneath each pad.

15. A method for producing a semiconductor circuit, the method comprising:
providing a pad for electrical bonding of the semiconductor circuit of the semiconductor circuit; and
providing a metal arrangement disposed beneath the pad, in a metal layer of the semiconductor circuit located closest to the pad, the metal arrangement disposed in an electrically insulated manner.

16. The method according to claim 15, wherein the metal arrangement is a full-area plate or comprises a regular structure.

17. The method according to claim 15, wherein:
if only one metal layer containing a metal arrangement is disposed beneath the pad, the metal arrangement fully overlaps all edges of the pad; and
if a plurality of metal layers each containing a metal arrangement is disposed beneath the pad, at least one of the metal arrangements fully overlaps all edges of the pad.

18. The method according to claim 15, wherein:
if only one metal layer containing a metal arrangement is disposed beneath the pad, the metal arrangement comprises small metal plates; and
if a plurality of metal layers each containing a metal arrangement is disposed beneath the pad, at least one of the metal arrangements comprises small metal plates.

19. The method according to claim 18, wherein the small metal plates have at least one of the same surface area or are disposed with a regular distribution.

20. The method according to claim 15, wherein the metal arrangement comprises small square metal plates which are disposed in a checkerboard manner, a distance between two adjacent small metal plates is equal in each case.

21. The method according to claim 20, wherein an edge length of each small metal plate is greater than a distance between two adjacent small metal plates.

22. The method according to claim 15, wherein:
if only one metal layer containing a metal arrangement is disposed beneath the pad, an insulating layer is disposed at least one of between the metal arrangement and the pad or between the metal arrangement and a strip conductor located beneath the metal arrangement, and
if a plurality of metal layers each containing a metal arrangement is disposed beneath the pad, an insulating layer is disposed at least one of between an uppermost metal arrangement and the pad, between adjacent metal arrangements, or between a lowermost metal arrangement and a strip conductor located beneath the lowermost metal arrangement.

23. The method according to claim 15, wherein the metal arrangement comprises first and second metal arrangements disposed adjacently, each of the first and second metal arrangements comprise small regular polygonal metal plates disposed in a regular manner, and the small metal plates of the second metal arrangement cover gaps between the small metal plates of the first metal arrangement.

24. The method according to claim 15, wherein the metal arrangement comprises first and second metal arrangements disposed adjacently, each of the first and second metal arrangements comprise small square metal plates disposed in a checkerboard manner, a distance between two adjacent small metal plates in each of the first and second metal arrangements is equal, and the small metal plates of the second metal arrangement cover gaps between the small metal plates of the first metal arrangement.

25. The method according to claim 24, wherein a middle point of each small metal plate in the second metal arrangement is offset from a middle point of a small metal plate disposed adjacently in the first metal arrangement by a distance which corresponds to half the distance between two small metal plates added to half an edge length of the small metal plates in the first metal arrangement, in orthogonal directions that are planar with the first and second metal arrangements.

26. The method according to claim 15, wherein the metal arrangement comprises a first metal arrangement containing a plurality of small metal plates, and a second metal arrangement adjacent to the first metal arrangement, the second metal arrangement contains a lattice arranged such that, in each case, a hole in the second metal arrangement is disposed over one of the small metal plates in the first metal arrangement and has a shape which corresponds to a shape of the corresponding small metal plate.

27. A method for producing a semiconductor circuit, the method comprising:
providing a plurality of pads for electrical bonding of the semiconductor circuit of the semiconductor circuit; and
providing a metal arrangement disposed beneath each pad, in a metal layer of the semiconductor circuit located closest to the pad, the metal arrangement disposed in an electrically insulated manner.

28. The method according to claim 27, wherein a plurality of metal layers, each containing a metal arrangement, is disposed beneath each pad.
